(19) United States
(12) Patent Application Publication
(10) Pub. No.: US 2007/0042536 A1
(43) Pub. Date: Feb. 22, 2007

(54) Thin film transistor and method for manufacturing the same

(76) Inventors: Chi-Wen Chen, Minsyong Township (TW); Jen-Chien Peng, Jhubei City (TW); Yun-Sheng Chen, Kaohsiung City (TW)

Correspondence Address: RABIN & Berdo, PC, 1101 14TH STREET, NW, SUITE 500, WASHINGTON, DC, 20005, US

(21) Appl. No.: 11/372,123

(22) Filed: Mar. 10, 2006

(30) Foreign Application Priority Data
Aug. 17, 2005 (TW) 94128074

(51) Int. Cl. H01L 21/84

(52) U.S. Cl. 438/149; 257/E29.117

(57) ABSTRACT

A method for manufacturing a thin film transistor of the invention comprises steps of: forming a gate electrode on a substrate; forming a gate insulating layer on the gate electrode; forming a polysilicon layer on the gate insulating layer; forming an etching-stop layer on the polysilicon layer and corresponding to the gate electrode; forming a heavily doped polysilicon layer on the etching-stop layer and the polysilicon layer, the heavily doped polysilicon layer exposing a part of the etching-stop layer; and forming a source electrode and a drain electrode on the heavily doped polysilicon layer, and the source and drain electrode relatively positioned above the two sides of the gate electrode.

This application claims the benefit of Taiwan Application Serial No. 094128074, filed Aug. 17, 2005, the subject matter of which is incorporated herein by reference.

### BACKGROUND OF THE INVENTION

1. Field of the Invention

The invention relates in general to a thin film transistor and a method for manufacturing the same, and more particularly to a method for manufacturing a thin film transistor omitted steps of ion implantation and activation.

2. Description of the Related Art

In the technology of thin film transistors, polysilicon thin film transistors (poly-Si TFTs) includes a heavily doped polysilicon layer as the conductive material, and therefore owns better driving capability. The method for manufacturing a conventional TFT is described with drawings, particularly the method for transforming the amorphous silicon layer into the polysilicon layer.

Referring to FIGS. 1A˜1D, which are flow charts schematically illustrating the method for manufacturing the conventional thin film transistor according to the related art. The method for manufacturing a thin film transistor 10 of the related art includes the following steps. Firstly, a gate electrode 12, a gate insulating layer 13, an amorphous silicon layer 14, and an etching-stop layer 15 are formed on the substrate 11 as shown in FIG. 1A.

Next, the amorphous silicon layer 14 is crystallized into a polysilicon layer 14′ in the specific air condition by the excimer laser annealing (ELA) process. Then, an ion implantation process is applied. That is, the predetermined dopants are ionized, and injected into the polysilicon layer 14′ by the accelerator, as shown in FIG. 1B. Afterward, an activation process is provided, and the atoms start to move caused of high temperature, so that dopants which rest on the surface of the polysilicon layer 14′ move into the lattice of the polysilicon layer 14′ to be valid dopants. Thus, heavily doped polysilicon layers 14a and 14b are formed as shown in FIG. 1C. Finally, the source electrode 18a and a drain electrode 18b are formed to accomplish the conventional thin film transistor 10 as shown in FIG. 1D.

In the conventional method for manufacturing the polysilicon thin film transistor, the ion implantation process remains the main process for preparing the heavily doped polysilicon layer. However, the equipments of the ion implantation process are expensive, and more activation process is needed after the ion implantation process, so that the ion implantation process is not only high-cost but also time-consuming. Further, when the heavily doped polysilicon layer is formed by the ion implantation process, the channel is subject to be polluted, and the electric characteristic is deteriorated.

### SUMMARY OF THE INVENTION

In view of the foregoing, it is an object of the present invention to provide a thin film transistor and a method for manufacturing the same. The heavily doped polysilicon layer of the thin film transistor is transformed from the heavily doped amorphous silicon layer by applying energy. The high-cost step of ion implantation and the time-consuming step of activation are omitted in the method of the present invention. It allows to reduce the cost, time and manpower, and to speed up the production rate.

The invention achieves the above-identified object by providing a method for fabricating a thin film transistor (TFT), comprising steps of: (a) forming a gate electrode on a substrate; forming a gate insulating layer on the gate electrode; (b) forming a polysilicon layer on the gate insulating layer; (c) forming an etching-stop layer on the polysilicon layer and corresponding to the gate electrode; (d) forming a heavily doped polysilicon layer on the etching-stop layer and the polysilicon layer, the heavily doped polysilicon layer exposing a part of the etching-stop layer; and (e) forming a source electrode and a drain electrode on the heavily doped polysilicon layer, and the source and drain electrodes positioned above the two sides of the gate electrode, respectively.

It is an object of the invention to provide another method for manufacturing a thin film transistor, comprising steps of: (a) forming a gate electrode on a substrate; (b) forming a gate insulating layer on the gate electrode; (c) forming an amorphous silicon layer on the gate insulating layer; (d) forming an insulating layer on the amorphous silicon layer; (e) patterning the insulating layer to form an etching-stop layer on the amorphous silicon layer and corresponding to the gate electrode; (f) forming a heavily doped amorphous layer on the amorphous silicon layer and the etching-stop layer; (g) applying energy to the amorphous silicon layer and the heavily doped amorphous silicon layer so as to transform them into a polysilicon layer and a heavily doped polysilicon layer, respectively; (h) forming a conductive layer on the heavily doped polysilicon layer; and (i) patterning a conductive layer and the heavily doped polysilicon layer to expose a part surface of the etching-stop layer so as to forming a source electrode and a drain electrode positioned above the two sides of the gate electrode, respectively.

It is an object of the invention to provide a thin film transistor (TFT), comprising a gate electrode, a gate insulating layer, a polysilicon layer, an etching-stop layer, a heavily doped polysilicon layer, a source electrode, and a drain electrode. The gate electrode is disposed on a substrate. The gate insulating layer is disposed on the gate electrode. The polysilicon layer, disposed on the gate insulating layer. The etching-stop layer is disposed on the polysilicon layer, and corresponding to the gate electrode so as to define a length of a channel. The heavily doped polysilicon layer is disposed on the polysilicon layer, and the heavily doped polysilicon layer having an aperture to expose a part surface of the etching-stop layer. The source electrode and a drain electrode are disposed on the heavily doped polysilicon layer, and positioned above the two sides of the gate electrode, respectively.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIGS. 1A˜1D are flow charts schematically illustrating the method for manufacturing the conventional thin film transistor according to the related art.

FIGS. 2A˜2G are flow charts schematically illustrating the method for manufacturing the thin film transistor according to the embodiment one of the present invention;

FIGS. 3A˜3C are flow charts schematically illustrating the method for manufacturing a thin film transistor according to embodiment two of the present invention;

FIGS. 4A and 4B are flow charts schematically illustrating the method for manufacturing a thin film transistor according to embodiment three of the present invention;

FIGS. 5A˜5C are flow charts schematically illustrating the method for manufacturing a thin film transistor according to embodiment four of the present invention; and

FIGS. 6A and 6B are flow charts schematically illustrating the method for manufacturing a thin film transistor according to embodiment five of the present invention.

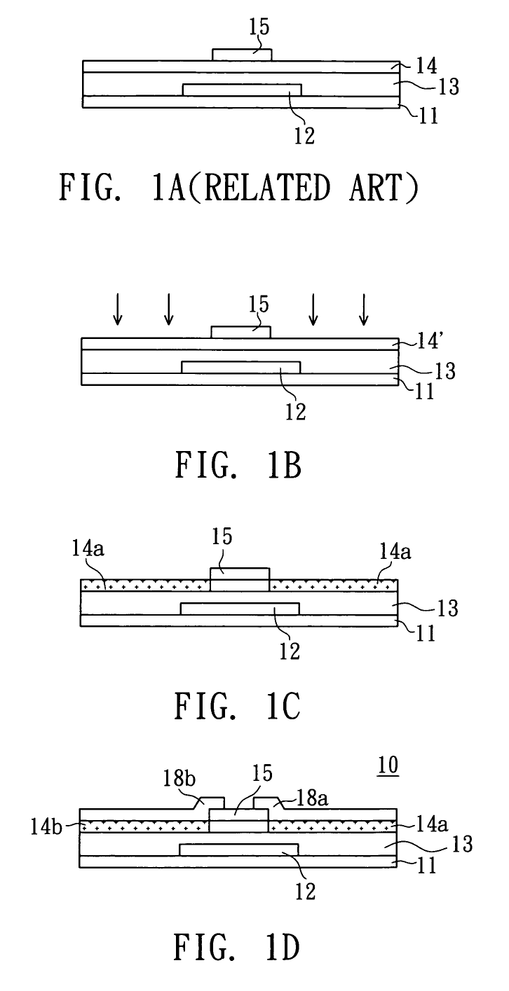

### DETAILED DESCRIPTION OF THE INVENTION

A method for manufacturing a thin film transistor of the invention comprises steps of: forming a gate electrode on a substrate; forming a gate insulating layer on the gate electrode; forming a polysilicon layer on the gate insulating layer; forming an etching-stop layer on the polysilicon layer corresponding to the gate electrode; forming a heavily doped polysilicon layer on the etching-stop layer and the polysilicon layer, and exposing a part of the etching-stop layer; and forming a source electrode and a drain electrode on the heavily doped polysilicon layer, and the source and drain electrodes positioned above the two sides of the gate electrode, respectively. Preferably, the polysilicon layer and the heavily doped polysilicon layer are formed by transforming an amorphous silicon layer and a heavily doped amorphous layer by applying energy. The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

### Embodiment One

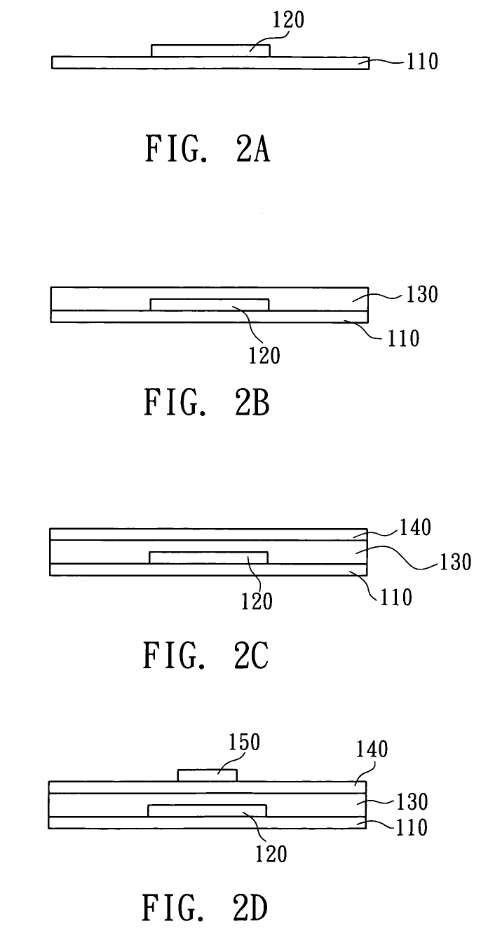

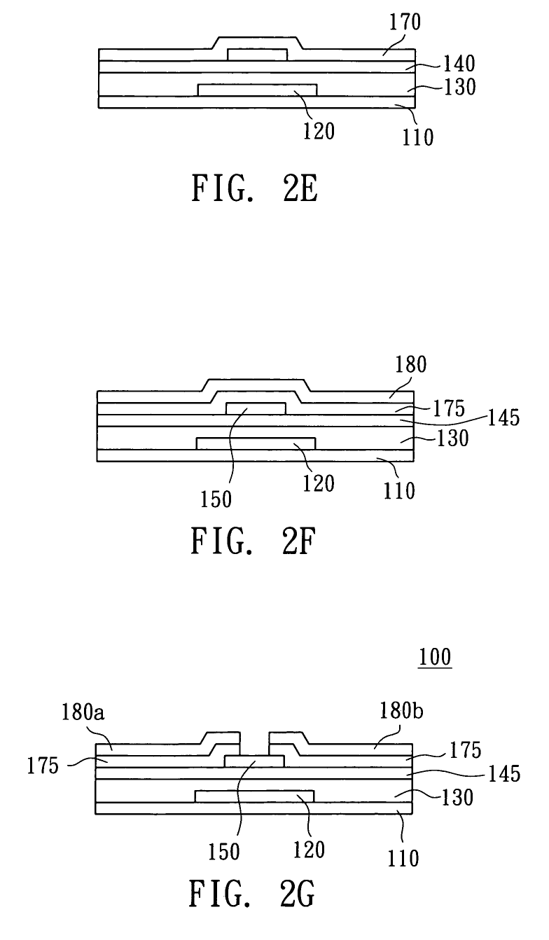

Referring to FIGS. 2A˜2G, which are flow charts schematically illustrating the method for manufacturing the thin film transistor according to the embodiment one of the present invention. The method for manufacturing the thin film transistor (TFT) 100 of the present embodiment includes following steps.

Firstly, a gate electrode 120 is formed on the substrate 110, as shown in FIG. 2A. Then, a gate insulating layer 130 is formed on and covering the gate electrode 120, as shown in FIG. 2B. Next, an amorphous silicon layer 140 is formed on the gate insulating layer 130, as shown in FIG. 2C. The amorphous silicon layer 140 is formed by a plasma-enhanced chemical vapor deposition (PECVD) or a chemical vapor deposition (CVD).

After an insulating layer (not shown) is formed on the amorphous silicon layer 140, the insulating layer is patterned to form an etching-stop layer 150 on the amorphous silicon layer 140 and overlapped corresponding to the gate electrode 120, as shown in FIG. 2D.

Next, a heavily doped amorphous silicon layer 170 is formed on the etching-stop layer 150 and the amorphous silicon layer 140, as shown in FIG. 2E. For example, the heavily doped amorphous silicon layer 170 is formed by a plasma-enhanced chemical vapor deposition (PECVD) or a chemical vapor deposition (CVD). Further, the TFT of the present embodiment can be an N type TFT or a P type TFT, so that the heavily doped amorphous silicon layer 170 could be an N type or P type doped amorphous silicon layer. For example, the heavily doped amorphous silicon 170 layer is deposited with phosphine (PH₃) and silane (SiH₄) gas to form an N type doped amorphous silicon layer. In addition, the heavily doped amorphous silicon layer 170 is deposited with diborane (B₂H₆) and silane (SiH₄) gas to form a P type doped amorphous silicon layer.

Afterward, energy is applied to the amorphous silicon layer 140 and the heavily doped amorphous silicon layer 170 to transform them into a polysilicon layer 145 and a heavily doped polysilicon layer 175, respectively. For example, the energy is a laser, a magnetic field, a heat source or a catalyst. Preferably, the energy, such as heat, is applied by a rapid thermal annealing (RTA) process or a field enhanced rapid thermal annealing (FERTA) process. Compared with the conventional method, the high-cost step of ion implantation and the time-consuming step of activation are omitted in the method of the present embodiment. It allows to reduce the cost, time and manpower, and to speed up the production rate.

After the heavily doped polysilicon layer 175 is formed on the etching-stop layer 150 and the polysilicon layer 145, a conductive layer 180 is formed on the heavily doped polysilicon layer 175, as shown in FIG. 2F. Finally, the conductive layer 180 and the heavily doped polysilicon layer 175 are patterned to expose part of the etching-stop layer 150, and then a source electrode 180a and a drain electrode 180b are formed, as shown in FIG. 2G. There is an aperture between the source electrode 180a and the drain electrode 180b exposing the part of the etching-stop layer 150.

In addition, the performing sequences of those steps are not limited, and those steps stated below also could be arranged in any other way. For example, the energy could be applied to transform the amorphous silicon layer into the polysilicon layer immediately after the amorphous silicon layer is formed. Then, the etching-stop layer, the heavily doped amorphous silicon layer are sequentially formed, and the energy is applied again to transform the heavily doped amorphous silicon layer into a heavily doped polysilicon layer.

### Embodiment Two

The method for manufacturing a thin film transistor according to embodiment two is similar to that of the embodiment one, but the main difference between the embodiment two and the embodiment one is a step of forming a lightly doped polysilicon layer. The other steps are the same, so they would not be described repeatedly in the following context.

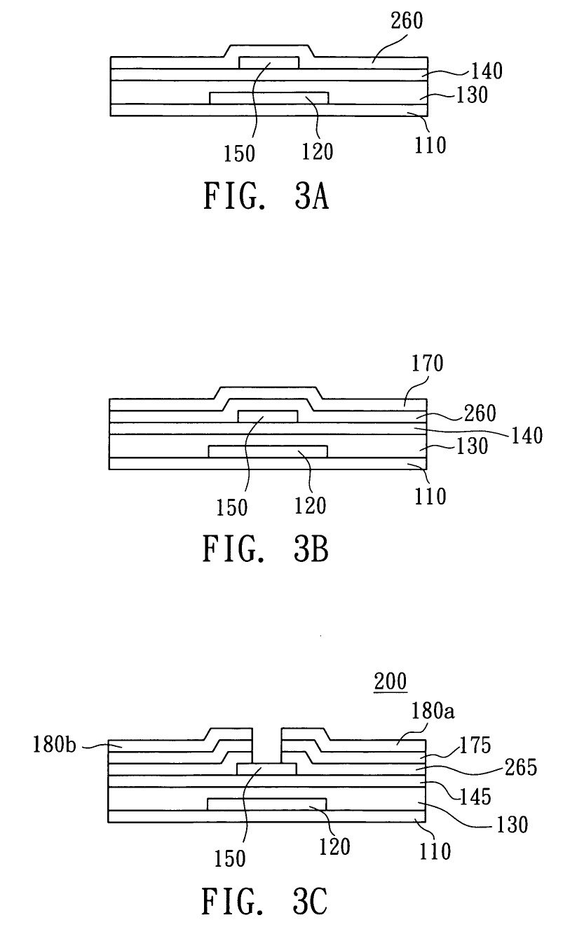

Referring to FIGS. 3A˜3C, which are flow charts schematically illustrating the method for manufacturing a thin film transistor according to embodiment two of the present invention. The method for manufacturing a thin film transistor 200 of the present embodiment includes following steps. Firstly, as stated in the embodiment one, a gate electrode 120, a gate insulating layer 130, an amorphous silicon layer 140, and an etching-stop layer 150 are sequentially formed on the substrate 110.

Then, another amorphous silicon layer 260 is formed on the amorphous silicon layer 140 and the etching-stop layer 150, as shown in FIG. 3A. Next, a heavily doped amorphous silicon layer 170 is formed on the another amorphous silicon layer 260, so that the another amorphous silicon layer 260 is positioned between the amorphous silicon layer 140 and the heavily doped amorphous silicon layer 170, as shown in FIG. 3B. Afterward, energy is applied in order to transfer dopants in the heavily doped amorphous silicon layer 170 to the another amorphous silicon layer 260, and also transform the another amorphous silicon layer 260 into a lightly doped polysilicon layer 265. Simultaneously, the energy transforms the amorphous silicon layer 140 and the heavily doped amorphous silicon layer 170 into a polysilicon layer 145 and a heavily doped polysilicon layer 175, respectively. Thus, the lightly doped polysilicon layer 265 is positioned between the polysilicon layer 145 and the heavily doped polysilicon layer 175. Finally, a source electrode 180a and a drain electrode 180b are formed to accomplish the thin film transistor 200 of the present embodiment, as shown in FIG. 3C.

In addition, the step of forming the lightly doped polysilicon layer is not limited. For example, the lightly doped polysilicon layer also could be formed by following steps. Firstly, a lightly doped amorphous silicon layer is deposited with small amount of the doped gas and silane (SiH₄) gas in the CVD or PECVD process. Then, the energy transforms those amorphous silicon layers into a polysilicon layer, a lightly doped polysilicon layer, and a heavily doped polysilicon layer.

The thin film transistor 200 of the present embodiment is classified into the lightly doped drain structure (LDD structure), and the lightly doped polysilicon layer serves as a buffer between the channel and the heavily doped polysilicon layer. It could reduce the electric field around the drain electrode. Thus, the leakage current and the reliability of devices can be improved.

### Embodiment Three

The method for manufacturing a thin film transistor according to embodiment three is similar to that of the embodiment one, but the main difference between the embodiment three and the embodiment one is a step of forming an etching-stop layer. The pattern of the etching-stop layer of the embodiment three is different from that of the embodiment one, so the structure of the TFT is inherently different. The other steps and structure are the same, so they would not be described repeatedly in the following context.

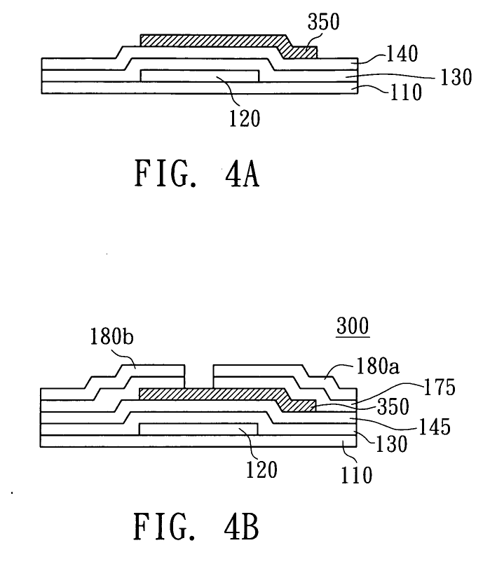

Referring to FIGS. 4A and 4B, which are flow charts schematically illustrating the method for manufacturing a thin film transistor according to embodiment three of the present invention. The method for manufacturing a thin film transistor 300 of the present embodiment includes following steps. Firstly, as stated in the embodiment one, a gate electrode 120, a gate insulating layer 130, an amorphous silicon layer 140, an insulating layer 350 are sequentially formed on the substrate 110. Then, the insulating layer 350 is patterned to form an etching-stop layer 350. The etching-stop layer 350 is wider than the gate electrode 120, and asymmetrically relative to the gate electrode 120 as shown in FIG. 4A. Preferably, at least one end of the etching-stop layer 350 extends out over one lateral side of the gate electrode 120. Finally, the heavily doped polysilicon layer 175, a source electrode 180a and a drain electrode 180b are sequentially formed to accomplishing the thin film transistor 300 of the present embodiment as shown in FIG. 4B.

Referring to FIG. 4B, the thin film transistor 300 includes a substrate 110, a gate electrode 120, a gate insulating layer 130, a polysilicon layer 145, an etching-stop layer 150, a lightly doped polysilicon layer 165, a heavily doped polysilicon layer 175, a source electrode 180a and a drain electrode 180b. The gate electrode 120 is disposed on the substrate 110, the gate insulating layer 130 is disposed on and covering the gate electrode 120. The polysilicon layer 145 is disposed on the gate insulating layer 130. The etching-stop layer 150 is disposed on the polysilicon layer 145, and corresponding to the gate electrode 120 so as to define a length of a channel. Preferably, the etching-stop layer 150 is wider than and asymmetrically relative to the gate electrode 120, and one side of the etching-stop layer 150 is extended out over the lateral side of the gate electrode 120. The heavily doped polysilicon layer 175 is disposed on the polysilicon layer 145, and the heavily doped polysilicon layer 175 has an aperture to expose a part surface of the etching-stop layer 150. The source electrode 180a and the drain electrode 180b are disposed on the heavily doped polysilicon layer 175, and positioned above the two sides of the gate electrode 120, respectively.

The thin film transistor 300 of the present embodiment is classified into the offset structure, the length of the channel defined by the etching-stop layer. In the present embodiment, a part of the polysilicon layer shielding by the etching-stop layer would not be controlled by the source or drain electrodes, and become an area having high resistance. It allows to reduce the electrical field around the drain electrode and to decrease the leakage current.

### Embodiment Four

The method for manufacturing a thin film transistor according to embodiment four is similar to that of the embodiment one, but the main difference between the embodiment four and the embodiment one is a step of forming the heavily doped polysilicon layer. The other steps are the same, so they would not be described repeatedly in the following context.

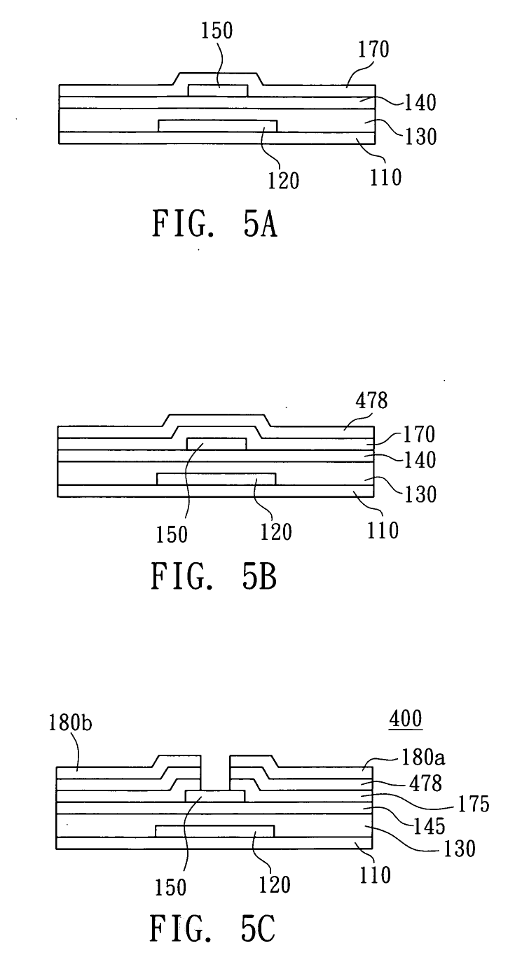

Referring to FIGS. 5A˜5C, which are flow charts schematically illustrating the method for manufacturing a thin film transistor according to embodiment four of the present invention. The method for manufacturing a thin film transistor 400 of the present embodiment includes following steps. Firstly, as stated in the embodiment one, a gate electrode 120, a gate insulating layer 130, an amorphous silicon layer 140, an etching-stop layer 150 are sequentially formed on the substrate 110. Then, a heavily doped amorphous silicon layer 170 is formed on the amorphous silicon layer 140 and the etching-stop layer 150 as shown in FIG. 5A. Next, a catalytic metal layer 478 is formed on the heavily doped amorphous silicon layer 170 as shown in. FIG. 5B. The catalytic metal layer 478 preferably comprises Nickel (Ni). Afterward, energy, such as heat, is applied to the amorphous silicon layer 140 and the heavily doped amorphous silicon layer 170 so as to transform them into a polysilicon layer 145 and a heavily doped polysilicon layer 175, respectively. The energy is preferably provided by a metal induced lateral crystallization (MILC) process. Finally, a source electrode 180a and a drain electrode 180b are formed to accomplish the thin film transistor 400 of the present embodiment as shown in FIG. 5C.

In the TFT 400, the catalytic metal layer 478 is positioned between the heavily doped polysilicon layer 175 and the source/drain electrodes 180a and 180b. Also, the catalytic metal layer 478 could be removed after forming the heavily doped polysilicon layer 175.

The thin film transistor 400 of the present embodiment is performed by the metal induced lateral crystallization (MILC) process. Metal silicide produced by catalytic metal layer and the amorphous silicon layer could catalyze the crystallization reaction by decrease the reaction temperature. It helps to shorten the manufacturing time.

### Embodiment Five

The method for manufacturing a thin film transistor according to embodiment five is similar to that of the embodiment one, but the main difference between the embodiment three and the embodiment one is a step of forming a polysilicon layer. The pattern of the polysilicon layer of the embodiment five is different from that of the embodiment one, so the structure of the TFT is inherently different. The other steps and structure are the same, so they would not be described repeatedly in the following context.

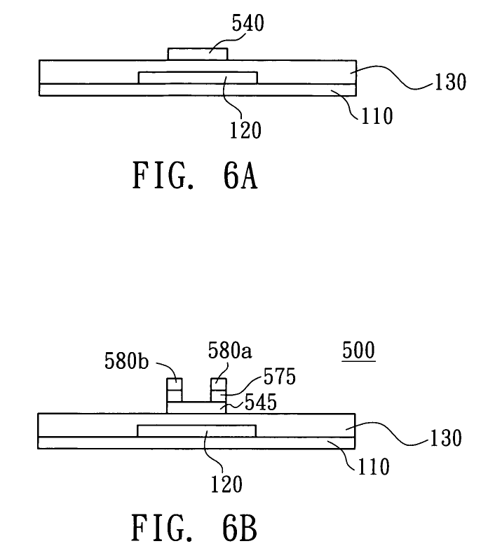

Referring to FIGS. 6A and 6B, which are flow charts schematically illustrating the method for manufacturing a thin film transistor according to embodiment five of the present invention. The method for manufacturing a thin film transistor 500 of the present embodiment includes following steps. Firstly, as stated in the embodiment one, a gate electrode 120, a gate insulating layer 130, an amorphous silicon layer 140 are sequentially formed on the substrate 110.

Then, the amorphous silicon layer 540 is patterned, so that the sectional area of the amorphous silicon layer 540 is smaller than the sectional area of the gate electrode 120 as shown in FIG. 6A. Next, a heavily doped amorphous silicon layer (not shown) is formed on the amorphous silicon layer 540, and energy is applied to transform them into a polysilicon layer 545 and a heavily doped polysilicon layer 575, respectively. Finally, a source electrode 582a and a drain electrode 580b are formed on the heavily doped polysilicon layer 575 to accomplish the thin film transistor 500 of the present embodiment as shown in FIG. 6B.

The combination of the polysilicon layer 545 and the heavily doped polysilicon layer 575 is so called island structure, and the TFT 500 of the present embodiment is classified into the island-in structure, that is, the area of the polysilicon layer 545 is smaller than that of the gate electrode 120. The island-in structure has many advantages, and one of them is stated below. In manipulating status, because the polysilicon layer 545 is protected by the gate electrode 120 from being irradiated by the backlight (under the substrate 110), the TFT 500 hardly generates photo-induced leakage current so as to own improved reliability.

As described hereinbefore, the thin film transistor and the method for manufacturing the same, whose the heavily doped polysilicon layer is transformed from the heavily doped amorphous silicon layer by applying energy, has many advantages. Compared with the conventional method, the high-cost step of ion implantation and the time-consuming step of activation are omitted in the method of the present embodiment. It allows to reduce the cost, time and manpower, and to speed up the production rate. Further, the metal induced lateral crystallization (MILC) process is provided in the embodiment four. Metal silicide produced by catalytic metal layer and the amorphous silicon layer could catalyze the crystallization reaction by decrease the reaction temperature. It helps to shorten the manufacturing time. In the other hand, the leakage current and the reliability of the devices can be improved in all of the TFT structures disclosed in the specification, such as the lightly doped drain structure (LDD structure), the offset structure, and the island-in structure.

While the invention has been described by way of example and in terms of several embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for fabricating a thin film transistor (TFT), comprising:
forming a gate electrode on a substrate;
forming a gate insulating layer on the gate electrode;
forming a polysilicon layer on the gate insulating layer;
forming an etching-stop layer on the polysilicon layer corresponding to the gate electrode;
forming a heavily doped polysilicon layer on the etching-stop layer and the polysilicon layer and exposing part of the etching-stop layer; and
forming a source electrode and a drain electrode on the heavily doped polysilicon layer, wherein the source and drain electrodes are positioned above the two sides of the gate electrode, respectively.

2. The method according to claim 1, wherein the step of forming the polysilicon layer comprises:
forming an amorphous silicon layer on the gate insulating layer; and
applying energy to the amorphous silicon layer so as to transform the amorphous silicon layer into the polysilicon layer.

3. The method according to claim 2, wherein the step of forming the heavily doped polysilicon layer comprises:
forming a heavily doped amorphous layer on the etching-stop layer and the polysilicon layer, wherein the energy is applied to the amorphous silicon layer and the heavily doped amorphous silicon layer so as to transform the amorphous silicon layer and the heavily doped amorphous silicon layer into the polysilicon layer and a heavily doped amorphous polysilicon layer, respectively.

4. The method according to claim 2, further comprising:
patterning the etching-stop layer so that the patterned etching-stop layer is wider than and asymmetrically relative to the gate electrode.

5. The method according to claim 4, wherein at least one side of the etching-stop layer is extended out over the lateral side of the gate electrode.

6. The method according to claim 2, further comprising:
patterning the amorphous silicon layer so that the sectional area of the amorphous silicon layer is smaller than the sectional area of the gate electrode.

7. The method according to claim 2, wherein the step of forming the amorphous silicon layer is performed by plasma-enhanced chemical vapor deposition (PECVD) or chemical vapor deposition (CVD).

8. The method according to claim 1, wherein the step of forming the heavily doped polysilicon layer comprises:
forming a heavily doped amorphous silicon layer on the etching-stop layer and the polysilicon layer; and
applying energy to the heavily doped amorphous layer so as to transform the heavily doped amorphous layer into the heavily doped polysilicon layer.

9. The method according to claim 8, wherein the step of forming the heavily doped amorphous layer is performed by plasma-enhanced chemical vapor deposition (PECVD) or chemical vapor deposition (CVD).

10. The method according to claim 8, wherein the step of forming the heavily doped amorphous silicon layer comprises depositing with phosphine (PH₃) and silane (SiH₄) gas to form a N type doped amorphous silicon layer.

11. The method according to claim 8, wherein the step of forming the heavily doped amorphous silicon layer comprises depositing with diborane (B₂H₆) and silane (SiH₄) gas to form a P type doped amorphous silicon layer.

12. The method according to claim 8, wherein the energy is laser beam, a magnetic field, heat or a catalyst.

13. The method according to claim 8, wherein the energy is applied by a rapid thermal annealing (RTA) process or a field enhanced rapid thermal annealing (FERTA) process.

14. The method according to claim 8, further comprising:
forming a catalytic metal layer on the heavily doped amorphous silicon layer.

15. The method according to claim 14, wherein the energy is applied by performing a metal induced lateral crystallization (MILC) process.

16. The method according to claim 1 further comprising:
forming a lightly doped polysilicon layer on the polysilicon layer and the heavily doped polysilicon layer.

17. The method according to claim 16, wherein the step of forming the lightly doped polysilicon layer comprises:
forming a lightly doped amorphous silicon layer between the polysilicon layer and the heavily doped polysilicon layer; and
applying energy to the lightly doped amorphous silicon layer to transform the lightly doped amorphous silicon layer into a lightly doped polysilicon layer.

18. The method according to claim 16, wherein the step of forming the lightly doped polysilicon layer comprises:
forming another amorphous silicon layer between the polysilicon layer and the heavily doped polysilicon layer; and
providing energy so as to transfer a plurality of dopants in the heavily doped polysilicon layer to the another amorphous silicon layer, and to transform the another amorphous silicon layer into the lightly doped polysilicon layer.

19. A method for manufacturing a thin film transistor, comprising:
forming a gate electrode on a substrate;
forming a gate insulating layer on the gate electrode;
forming an amorphous silicon layer on the gate insulating layer;
forming an insulating layer on the amorphous silicon layer;
patterning the insulating layer to form an etching-stop layer on the amorphous silicon layer and corresponding to the gate electrode;
forming a heavily doped amorphous layer on the amorphous silicon layer and the etching-stop layer;
applying energy to the amorphous silicon layer and the heavily doped amorphous silicon layer so as to transform the amorphous silicon layer and the heavily doped amorphous silicon layer into a polysilicon layer and a heavily doped polysilicon layer, respectively;
forming a conductive layer on the heavily doped polysilicon layer; and
patterning the conductive layer and the heavily doped polysilicon layer to expose the part of the etching-stop layer so as to form a source electrode and a drain electrode positioned above the two sides of the gate electrode, respectively.

20. The method according to claim 19, further comprising:
forming a lightly doped amorphous silicon layer between the amorphous silicon layer and the heavily amorphous silicon layer, and transforming the lightly doped amorphous silicon layer into a lightly doped polysilicon layer by the energy before the step of forming the heavily amorphous silicon layer.

21. The method according to claim 19, further comprising:
forming another amorphous silicon layer between the amorphous silicon layer and the heavily doped amorphous silicon layer, and transforming the another amorphous silicon layer into a lightly doped polysilicon layer by the energy before the step of forming the heavily doped amorphous silicon layer.

22. The method according to claim 20, wherein the step of forming the amorphous silicon layer is performed by plasma-enhanced chemical vapor deposition (PECVD) or chemical vapor deposition (CVD).

23. The method according to claim 20, wherein the step of forming the heavily doped amorphous silicon layer is performed by plasma-enhanced chemical vapor deposition (PECVD) or chemical vapor deposition (CVD).

24. The method according to claim 20, wherein the step of forming the heavily doped amorphous silicon layer comprises depositing with phosphine (PH₃) and silane (SiH₄) gas to form a N type doped amorphous silicon layer.

25. The method according to claim 20, wherein the step of forming the heavily doped amorphous silicon layer comprises depositing with diborane (B₂H₆) and silane (SiH₄) gas to form a P type doped amorphous silicon layer.

26. The method according to claim 20, wherein the energy is laser beam, a magnetic field, heat or a catalyst.

27. The method according to claim 25, wherein the energy is applied by performing a rapid thermal annealing (RTA) process or a field enhanced rapid thermal annealing (FERTA) process.

28. The method according to claim 19 further comprising:
forming a catalytic metal layer on the heavily doped amorphous silicon layer.

29. The method according to claim 28, wherein the energy is applied by performing a metal induced lateral crystallization (MILC) process.
